(19) United States
(12) Patent Application Publication
(10) Pub. No.: US 2002/0117719 A1
(43) Pub. Date: Aug. 29, 2002

(54) Thin film transistor and active matrix type liquid crystal display device

(76) Inventors: Masahiko Ando, Hitachinaka (JP); Masahiro Kawasaki, Hitachi (JP); Masatoshi Wakagi, Hitachi (JP)

Correspondence Address: DICKSTEIN SHAPIRO MORIN & OSHINSKY LLP, 2101 L STREET NW, WASHINGTON, DC, 20037-1526, US

(21) Appl. No.: 09/949,846

(22) Filed: Sep. 12, 2001

(30) Foreign Application Priority Data
Feb. 26, 2001 (JP) 2001-049982

(51) Int. Cl. H01L 27/01

(52) U.S. Cl. 257/347

(57) ABSTRACT

A gate electrode, a gate insulating layer, a semiconductor layer, a drain electrode, a source electrode and a passivation insulating layer are fabricated in turn on an insulating substrate, thereby forming a thin film transistor. The thin film transistor is designed in such a way that a silicon oxide film is employed as a second gate insulating layer adjacent to the semiconductor layer; a thickness of the silicon oxide film is set to the range of 0.5 to 3.0 nm; and it shows the characteristics in which when a stress voltage which is negative with respect to the drain electrode and the source electrode is applied to the gate electrode, the operating threshold voltage is reduced.

### BACKGROUND OF THE INVENTION

1. Field of the invention

The present invention relates in general to a thin film transistor and an active matrix type liquid crystal display device. More particularly, the invention relates to a thin film transistor which is suitable for being employed as a switching device showing the enhancement type switching characteristics, and an active matrix type liquid crystal display device employing the same.

2. Description of the Related Art

In general, in active matrix type liquid crystal display devices, a large number of thin film transistors are adopted as the switching devices in display units and drive units. The thin film transistor shows the so-called switching operation in which as the gate voltage is increased with a fixed voltage applied to a drain electrode and a source electrode, at the time when the gate voltage becomes equal to or larger than a predetermined value, the value of a current which is caused to flow through the drain and source is abruptly increased by equal to or larger than six orders of magnitude. The gate voltage at this time is called the operating threshold voltage Vth.

In the conventional thin film transistor, Vth is in the range of about 0±2 V. Thus, when the gate voltage is equal to or larger than Vth, the value of the current (ON current) which is caused to flow through the drain electrode and the source electrode is high, and hence the thin film transistor shows the ON state, while when the gate voltage is equal to or smaller than Vth, the thin film transistor shows the OFF state in which the value of the current (OFF current) which is caused to flow through the drain electrode and the source electrode is lower than that in the ON state by about equal to or larger than six orders of magnitude.

On the other hand, there is proposed the thin film transistor having the so-called enhancement type switching characteristics in which it shows the switching operation at Vth equal to or larger than the maximum voltage of the liquid crystal driving voltage required for the optical modulation of the liquid crystal, e.g., at Vth equal to or larger than 10 V.

As for an active matrix type liquid crystal display device employing this thin film transistor as the switching device, for example, there is an active matrix type liquid crystal display device of an IPS (In Plane Switching) system (lateral electric field system) made by the present applicant for letters patent (refer to Japanese Patent Application No. 283830 of 1999 which will hereinafter be referred to as a prior art example).

In the liquid crystal display device of the IPS system, the scanning wirings, the signal wirings and the common wiring are formed on the same insulating substrate; the two electrodes (the pixel electrode and the common electrode) are formed into the sinking comb-like shape; and the electric field which is roughly parallel with each of one pair of substrates is applied to the liquid crystal which is held between the one pair of substrates to drive the liquid crystal molecules in the direction parallel with each of the one pair of substrates in such a way that the shape of each of the liquid crystal molecules is not changed depending on the angle at which a user views the liquid crystal display device of interest. In such a manner, there is adopted the structure therefore in which the wider angle of field is obtained as compared with the conventional liquid crystal display device, and which is optimal for being employed as the direct viewing monitor.

On the contrary, in the liquid crystal display device of the IPS system, since the opaque electrode is formed into the sinking comb-like shape, a part of the incident light is shaded by the pixel electrode(s) and hence the area of the aperture which can transmit the light is small so that the display screen becomes dark. For this reason, since the back light is employed in order to light up the display screen, the power consumption becomes large. Then, in the prior art example, as described in JP-A-8-62578, there is adopted the common wiringless IPS system in which the scanning wiring is made also serve a part of the common wiring for supplying the voltage from the outside to the common electrode, whereby the common wiring is omitted to increase the aperture area of the IPS system. Thereby, the high luminance and low power consumption active matrix type liquid crystal display device based on the IPS system is realized.

In the active matrix type liquid crystal display device based on the above-mentioned IPS system, as the thin film transistor showing the enhancement type switching characteristics, there is employed one in which a gate electrode, a gate insulating film, a semiconductor layer, a drain electrode, a source electrode and a passivation insulating film are fabricated in turn on an insulating substrate, and a silicon oxide film is formed on a part, of the gate insulating film, which is adjacent to the semiconductor layer (the adjacent area). In this case, the silicon oxide film in the adjacent part is formed at the composition ratio of oxygen to silicon of equal to or larger than 1.7 by utilizing the plasma enhanced chemical vapor deposition (CVD) method using the mixed gas of SiH₄ and N₂O in such a way as to have a thickness of about 10 nm.

### SUMMARY OF THE INVENTION

In the light of the foregoing, it is therefore an object of the present invention to provide a thin film transistor which is capable of carrying out the stable switching operation, and a method of manufacturing the same.

It is another object of the present invention to provide an active matrix type liquid crystal display device employing a thin film transistor which is capable of carrying out the stable switching operation.

When adopting the thin film transistor in the active matrix type liquid crystal display device, as a result of measuring the dependency of Vth on the stress voltage with respect to the conventional thin film transistor in which the gate insulating film made of silicon nitride and the semiconductor layer made of silicon are adjacent to each other and the thin film transistor of the prior art example in which the silicon oxide film is formed in a part, of the gate insulating film, which is adjacent to the semiconductor layer, the measurement results as shown in FIG. 3 are obtained. FIG. 3 shows the dependency of Vth on the stress voltage when the voltage of 0 V is applied to the drain electrode and the source electrode of the thin film transistor and each of the positive and negative stress voltages is applied to the gate voltage for 1,000 seconds.

In FIG. 3, it is understood that since in the conventional thin film transistor, no silicon oxide film is contained in the gate insulating film, as shown in the characteristics A, Vth is roughly held at the fixed value in the range of the applied voltage from about −50 V to about +50 V, and at the applied voltage equal to or smaller than about −50 V and also at the applied voltage equal to or larger than about +50 V, Vth is shifted in the direction coinciding with the polarity of the stress voltage.

On the other hand, in the thin film transistor of the prior art example, it is understood that as shown in the characteristics B, there is hardly the voltage range in which Vth is held at the fixed value against the negative stress voltage, and Vth is monotonously increased as the stress voltage which is zero or the negative value is increased. The phenomenon that Vth is monotonously increased as the stress voltage is increased results in that during the display operation of the liquid crystal display device, Vth is increased. Thus, if during the display operation of the liquid crystal display device, Vth is increased, then the applied voltage to the liquid crystal becomes insufficient and hence the display luminance may be reduced in some cases. By the way, the phenomenon that Vth becomes unstable, as described in an article of J. H. Kim et al., Journal of Applied Physics 76, 7601 (1994) for example, is considered as the problem that arises generally in the thin film transistor in which the silicon oxide film is employed in a part, of the gate insulating film, which is adjacent to the semiconductor layer.

In addition, when processing the gate insulating film, in general, for the process of the gate insulating film, the dry etching method using the fluorine series gas such as SF₆ gas is utilized. Thus, when processing and removing the gate insulating film formed of the silicon nitride single layer, e.g., when forming the process hole passing through the gate insulating film, for the overall region of the process hole, the process of the forward taper shape in which the angle between the end face of the process hole and the substrate surface becomes smaller than 90 degrees is required.

However, in the case where the gate insulating film is made of silicon nitride and silicon oxide, and a part of the gate insulating film in which the silicon oxide film is formed on the silicon nitride film is processed and removed by utilizing the etching, since the etching rate of silicon oxide is slower than that of silicon nitride, the silicon oxide film having the slower etching rate is projected in the eaves-like shape on the silicon nitride film so that the angle between the end face of the process hole and the substrate surface becomes equal to or larger than 90 degrees and hence a part of the process hole is formed into a reverse taper shape. If the reverse taper shape part is formed in a part of the process hole, then when a metal layer is inserted into the process hole so that the gate electrode or the scanning wiring and the metal thin film formed in such a way as to overlie the gate insulating film are electrically connected to each other through the process hole formed through the gate insulating film, a crack(s) is(are) generated in the metal thin film due to the reverse taper shape part. As a result, the sufficient electrical connection may not be obtained in some cases.

It is therefore still another object of the present invention to provide a thin film transistor which is capable of carrying out the stable switching operation, and a method of manufacturing the same, and an active matrix type liquid crystal display device employing the same.

In order to attain the above-mentioned objects, according to the present invention, there is provided a thin film transistor, wherein a gate electrode, a gate insulating layer, a semiconductor layer, a drain electrode, a source electrode and a passivation insulating layer are fabricated in turn on an insulating substrate; a part, of the gate insulating layer, which is adjacent to the semiconductor layer is made of an oxide film; and when a stress voltage which is negative with respect to the drain electrode and the source electrode is applied to the gate electrode, an operating threshold voltage is reduced.

When structuring the above-mentioned thin film transistor, the following elements can be added.

(1) The operating threshold voltage when releasing the condition of applying the negative stress voltage to the gate electrode is equal to or larger than a liquid crystal driving voltage.

(2) The part, of the gate insulating layer, which is adjacent to the semiconductor layer is formed of a silicon oxide film having a thickness which is equal to or larger than 0.5 nm, but is equal to or smaller than 3.0 nm.

(3) The silicon oxide film has a composition ratio of oxygen to silicon which is equal to or larger than 1.7.

In addition, according to the present invention, there is provided a thin film transistor, wherein a gate electrode, a gate insulating layer, a semiconductor layer, a drain electrode, a source electrode and a passivation insulating layer are fabricated in turn on an insulating substrate; a part, of the gate insulating layer, which is adjacent to the semiconductor layer is made of an oxide film; and the part, of the gate insulating layer, which is adjacent to the semiconductor layer is made of a silicon oxide film having a thickness which is equal to or larger than 0.5 nm, but is equal to or smaller than 3.0 nm.

When structuring the above-mentioned thin film transistor, it can be structured by employing the silicon oxide film having a composition ratio of oxygen to silicon which is equal to or larger than 1.7.

When structuring each of the thin film transistors, the following elements can be added.

(1) A process hole passing through a part of the gate insulating layer is formed through the gate insulating layer; the process hole is formed into a forward taper shape in which an angle between the end face of the process hole and the insulating substrate surface is smaller than 90 degrees; and a metal layer is inserted into the process hole.

In addition, when manufacturing any one of the above-mentioned thin film transistors, the present invention adopts a method of manufacturing a thin film transistor, wherein the step of forming a first gate insulating layer, made of silicon nitride, as a gate insulating layer on a gate electrode by utilizing the plasma enhanced chemical vapor deposition method, the step of exposing the silicon nitride surface to the oxygen plasma to oxidize the silicon nitride surface to form a second gate insulating layer made of silicon oxide on the first gate insulating layer made of silicon nitride, and the step of forming a silicon semiconductor film as a semiconductor layer on the second gate insulating layer made of silicon oxide by utilizing the plasma enhanced chemical vapor deposition method are continuously implemented without breaking the vacuum.

In accordance with the above-mentioned means, since the part, of the gate insulating film, which is adjacent to the semiconductor layer is made of oxide film, and the thin film transistor shows the characteristics in which when applying a stress voltage which is negative with respect to the drain electrode and the source electrode to the gate electrode, the operating threshold voltage is reduced, the switching operation can be stably carried out.

In addition, since the part, of the gate insulating film, which is adjacent to the semiconductor layer is made of the oxide film, and also the part, of the gate insulating film, which is adjacent to the semiconductor layer is made of the silicon oxide film having a thickness which is equal to or larger than 0.5 nm, but is equal to or smaller than 3.0 nm, the thin film transistor shows the characteristics in which when applying a stress voltage which is negative with respect to the drain electrode and the source electrode to the gate electrode, the operating threshold voltage is reduced. Therefore, the stable switching operation can be carried out. That is, in the case where as the operating threshold voltage when releasing the condition of applying the negative stress voltage to the gate electrode, the voltage equal to or larger than the liquid crystal driving voltage, e.g., equal to or larger than 10 V is applied to the gate electrode, the stable switching operation can be carried out.

In addition, since the part, of the gate insulating film, which is adjacent to the semiconductor layer is made of the silicon oxide film having a thickness which is equal to or larger than 0.5 nm, but is equal to or smaller than 3.0 nm, when forming the process hole through the gate insulating film, the process hole having the forward taper shape in which the angle between the end face of the process hole and the insulating substrate surface is smaller than 90 degrees can also be formed. Also, even when the gate electrode or the scanning electrode is electrically connected to the metal thin film which is formed in such a way as to overlie the gate insulating film through the metal layer, no crack is generated in the metal thin film at all, and hence the sufficient electrical connection can be obtained.

When the above-mentioned thin film transistor is employed as the switching device in the display device, it can be employed in the active matrix type display device including a switching device in a display unit or a drive unit.

In addition, when the above-mentioned thin film transistor is employed in the active matrix type liquid crystal display device having a switching device, the active matrix type liquid crystal display device having the following functions is desirable.

(1) An active matrix type liquid crystal display device including one pair of substrates at least one of which is transparent, and a liquid crystal layer held between the one pair of substrates, in which a plurality of scanning wirings and a plurality of signal wirings are formed in a matrix on one of the one pair of substrates; a switching device, a pixel electrode and one set of common electrodes are respectively formed in each of the vicinities of crossing parts at which the scanning wirings and the signal wirings intersect each other; a gate electrode of each of the switching devices is connected to any one of the scanning wirings; a drain electrode of each of the switching devices is connected to any one of the signal wirings; a source electrode of each of the switching devices is connected to the associated one of pixel elements; each of the plurality sets of common electrodes are connected to the associated one of the scanning wirings to be arranged between the pixel electrodes; and an electric field which is parallel with each of the one pair of substrates is formed between one of each of the plurality sets of common electrodes and the other of each of the plurality sets of common electrodes.

(2) An active matrix type liquid crystal display device including one pair of substrates at least one of which is transparent, and a liquid crystal layer held between the one pair of substrates, in which a plurality of scanning wirings and a plurality of signal wirings are formed in a matrix on one of the one pair of substrates; a switching device, and a pixel electrode are respectively formed in each of the vicinities of crossing parts at which the scanning wirings and the signal wirings intersect each other; a gate electrode of each of the switching devices is connected to any one of the scanning wirings; a drain electrode of each of the switching devices is connected to any one of the signal wirings; a source electrode of each of the switching devices is connected to the associated one of pixel elements; each of the pixel electrodes is connected to any one of the scanning wirings; a common electrode is formed in the other of the one pair of substrates; an electric field which is vertical to each of the one pair of substrates is formed between each of the pixel electrodes and the common electrode; the reference voltage is applied to the common electrode; and a liquid crystal driving voltage having the polarity which is changed in the positive direction or the negative direction with respect to the reference voltage is applied to each of the pixel electrodes.

As described above, according to the present invention, since a part, of a gate insulating film, which is adjacent to a semiconductor layer is made of an oxide film so that a thin film transistor shows the characteristics in which when a stress voltage which is negative with respect to a drain electrode and a source electrode is applied to a gate electrode, the operating threshold voltage is decreased, the switching operation can be stably carried out.

In addition, according to the present invention, it is possible to contribute to the promotion of the low power consumption and the improvement in the productivity of a liquid crystal display device.

### BRIEF DESCRIPTION OF THE DRAWINGS

The above and other objects as well as advantages of the present invention will become clear by the following description of the embodiment of the present invention with reference to the accompanying drawings, wherein:

FIG. 1 is a vertical cross sectional view of a thin film transistor according to an embodiment of the present invention;

FIG. 2 is a graphical representation useful in explaining the Id-Vg characteristics of a thin film transistor;

FIG. 3 is a graphical representation useful in explaining the dependency of the operating threshold voltage on the gate stress voltage of a thin film transistor;

FIG. 4 is a graphical representation useful in explaining the dependency of Vth and a Vth shift amount on the thickness of the silicon oxide film in a thin film transistor;

FIG. 5 is a graphical representation useful in explaining the dependency of an amount of electric charges injected into the gate insulating film on the thickness of the oxide film in a thin film transistor; and

FIG. 6 is a graphical representation useful in explaining the dependency of the number of connection defectives on the thickness of the oxide film in a thin film transistor.

### DESCRIPTION OF THE EMBODIMENTS

An embodiment of the present invention will hereinbelow be described in detail with reference to the accompanying drawings.

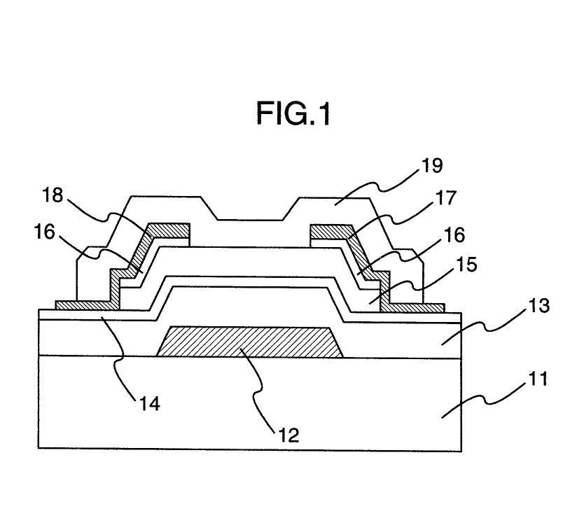

FIG. 1 is a vertical cross sectional view of a thin film transistor according to an embodiment of the present invention. In FIG. 1, a thin film transistor in the present embodiment is formed into the so-called inverted stagger structure in which a source electrode and a drain electrode are fabricated above a gate electrode, and the elements of the thin film transistor are fabricated on a glass substrate 11. That is, a gate electrode 12 made of Cr, a first insulating layer (gate insulating film) 13 made of silicon nitride, a second gate insulating layer (gate insulating film) 14 made of silicon oxide, a semiconductor layer 15 made of amorphous silicon, a contact layer 16 made of n⁺ type amorphous silicon doped with phosphorus, a source electrode 17 and a drain electrode 18 each of which is made of Cr, and a passivation insulating layer (passivation insulating film) 19 made of silicon oxide are fabricated (formed) in turn on the glass substrate 11.

The second insulating layer 14 of the gate insulating layer is formed of an oxide film which is formed in a part adjacent to the semiconductor layer 15 (adjacent region), e.g., a silicon oxide film having a thickness which is equal to or larger than 0.5 nm, but is equal to or smaller than 3.0 nm. Then, the thin film transistor is structured in such a way as to show the characteristics in which when the voltage of 0 V is applied to the drain electrode 18 and the source electrode 17, and the negative stress voltage is applied to the gate electrode 12, the operating threshold voltage is reduced.

Next, prior to the description of the characteristics of the thin film transistor having the above-mentioned structure, the description will hereinbelow be given with respect to a method of manufacturing the thin film transistor.

When manufacturing the thin film transistor, first of all, a Cr film with about 120 nm thickness is formed on the glass substrate 11 (Corning #1737) by utilizing the sputtering method. Thereafter, the Cr film on the glass substrate 11 is patterned by utilizing the photoetching method to form the gate electrode 12. Next, the thin films are successively formed as follows by utilizing the plasma enhanced chemical vapor deposition (CVD) method.

First of all, the first gate insulating layer 13 formed of a silicon nitride film with 300 nm thickness is formed using the mixed gas of SiH₄, NH₃, N₂ and the like. Thereafter, the surface of the silicon nitride film is exposed to the O₂ plasma for 100 seconds to form the second gate insulating layer 14 formed of a silicon oxide film with about 1 nm thickness on the first gate insulating layer 13.

Next, an amorphous silicon film with about 150 nm thickness is formed on the second gate insulating layer 14 using the mixed gas of SiH₄ and H₂, and then an n⁺ type amorphous silicon film with about 30 nm thickness is formed on the amorphous silicon film using the mixed gas of SiH₄ and PH₃. When forming these thin films, it is desirable that the processes therefore are continuously carried out without breaking the vacuum.

Furthermore, the n⁺ type amorphous silicon film and the amorphous silicon film are patterned at the same time into the island shape by utilizing the photoetching to form the semiconductor layer 15. Then, a Cr film with about 120 nm thickness which has been formed over the semiconductor layer 15 by utilizing the sputtering method is patterned by utilizing the photoetching to form the source electrode 17 and the drain electrode 18.

Thereafter, the n⁺ type amorphous silicon film between the source electrode 17 and the drain electrode 18 is removed by utilizing the etching method to form the contact layer 16 between the source electrode 17 and the drain electrode 18, and the semiconductor layer 15.

Next, a silicon oxide film with about 300 nm thickness which has been deposited onto the semiconductor layer 15, and the source electrode 17 and the drain electrode 18 by utilizing the plasma enhanced CVD method using the mixed gas of SiH₄ and N₂O for example is patterned by the photoetching to form the passivation insulating layer 19. That is, as a result, the thin film transistor having the inverted stagger structure is completed.

When structuring the above-mentioned thin film transistor, for the thin film transistor showing the so-called enhancement type switching characteristics in which the switching operation is carried out at Vth equal to or larger than the maximum voltage of the liquid crystal driving voltage required for the optical modulation of the liquid crystal, e.g., equal to or larger than 10 V, the composition ratio X of the silicon oxide (silicon oxide film) SiOx (the composition ratio of oxygen to silicon) which is used in each of the gate insulating layer 14 and the passivation insulating layer 19 is set equal to or larger than 1.7.

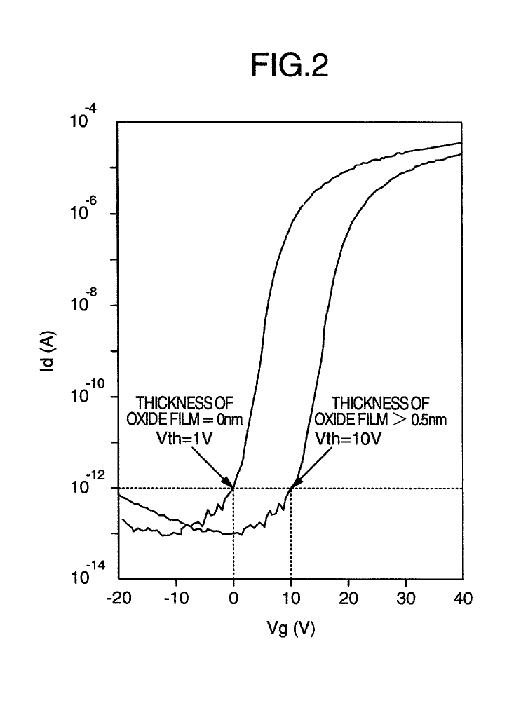

Next, as a result of measuring the dependency of the drain current on the gate voltage (Id-Vg characteristics) of the thin film transistor according to the present invention, the measurement results as shown in FIG. 2 are obtained.

In FIG. 2, it is understood that the operating threshold voltage Vth defined by the gate voltage at which the drain current becomes 1×10⁻¹² a is about 1 V in the case of the conventional thin film transistor in which the gate insulating film has no silicon oxide film, whereas it is 10 V in the case of the thin film transistor, according to the present invention, in which the silicon oxide film is adjacent to the semiconductor layer 15 made of amorphous silicon and hence the thin film transistor shows the objective enhancement type switching characteristics.

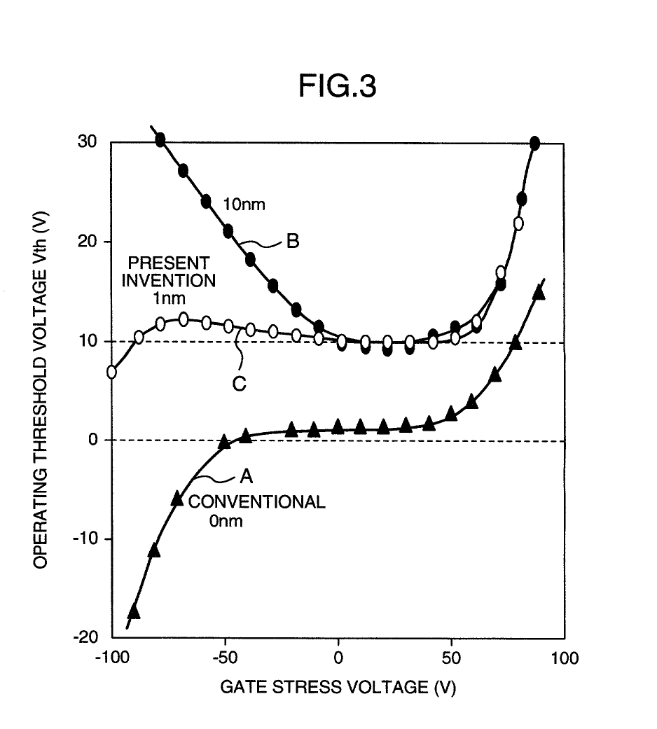

Next, as a result of measuring the dependency of the operating threshold voltage Vth on the gate stress voltage, the measurement results as shown in FIG. 3 are obtained. When measuring the dependency of the operating threshold voltage Vth on the gate stress voltage, 0 V is applied to the drain lectrode and the source electrode of the thin film transistor, and the stress voltage is applied to the gate electrode for 1,000 seconds.

In FIG. 3, in the case of the thin film transistor having the conventional structure in which the gate insulating layer has no silicon oxide film, as shown in the characteristics A, Vth before applying the gate stress voltage is 1 V, and Vth is hardly shifted against the stress voltage in the range of about −50 to about +50 V. But, against the stress voltage equal to or larger than 50 V, Vth is shifted in the direction coinciding with the polarity of the stress voltage.

On the other hand, in the case of the prior art example in which the silicon oxide film is employed in the gate insulating layer, and this silicon oxide film has a thickness of 10 nm, as shown in the characteristics B, Vth before applying the gate stress voltage is 10 V and hence the thin film transistor shows the desired enhancement type switching characteristics, and also against the positive stress voltage, the stability of Vth is equal to that in the conventional structure. However, against the negative stress voltage, there is hardly the voltage range in which Vth is held fixed, and Vth is abruptly monotonously increased as the positive or negative stress voltage is increased. That is, while the thin film transistor of the prior art example shows the enhancement type switching characteristics, if Vth is increased during the display operation of the liquid crystal display device, the applied voltage to the LIQUID crystal becomes insufficient to reduce the display luminance.

Also, on the other hand, in the case of the thin film transistor according to the present invention, as shown in the characteristics C, since the second gate layer of the insulating layer is formed of the silicon oxide film with 1 nm thickness, the thin film transistor shows the characteristics in which Vth is hardly changed against the negative stress voltage up to equal to or larger than −50 V and against the stress voltage equal to or larger than −70 V, Vth is reduced in the negative direction coinciding with the polarity of the stress voltage. This shows the effect of the stabilization of Vth due to the thinning of the silicon oxide film.

Therefore, when the thin film transistor according to the present invention is employed as the switching device of the active matrix type liquid crystal display device, even if Vth is increased during the display operation of the liquid crystal display device, the applied voltage to the liquid crystal can be sufficiently ensured and hence it is possible to suppress the reduction of the display luminance.

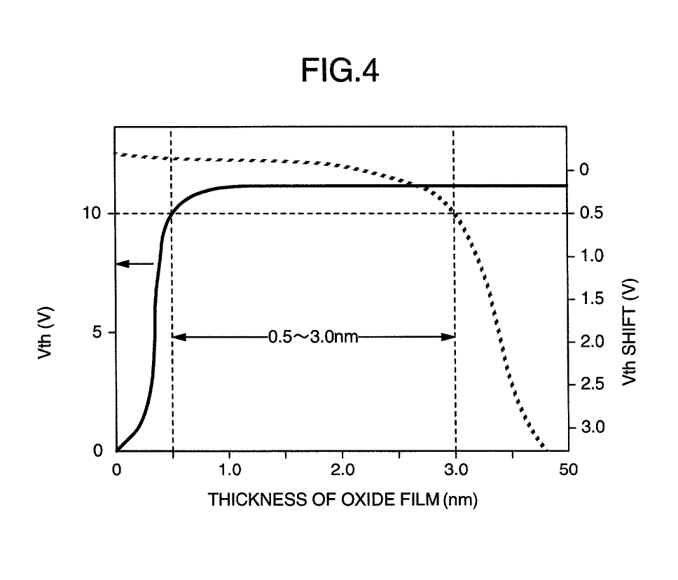

Next, the ground that the second gate insulating layer 14 is formed of the silicon oxide film having a thickness which is equal to or larger than 0.5 nm, but is equal to or smaller than 3 nm will hereinbelow be described on the basis of the dependency of Vth and a Vth shift amount on the thickness of the silicon oxide film shown in FIG. 4. In this case, the condition of applying the gate stress voltage is such that the applied voltage is −10 V and a period of time thereof is 1,000 seconds, and the composition ratio of silicon oxide SiOx is equal to or larger than 1.7.

From FIG. 4, it is understood that Vth has a tendency to saturate after having been abruptly increased along with the increase of the thickness of the silicon oxide film, and hence in order to obtain Vth equal to or larger than 10 V, the silicon oxide film needs to have the thickness equal to or larger than about 0.5 nm. In addition, when the thickness of the silicon oxide film is equal to or larger than about 3.0 nm, a Vth shift amount exceeds 0.5 V to be abruptly increased so that Vth becomes unstable.

As a result, it is understood that in order to obtain the stable enhancement type switching characteristics, the thickness of the silicon oxide layer (the second gate layer 14) adjacent to the semiconductor layer 15 needs to be set equal to or larger than about 0.5 nm, but equal to or smaller than 3.0 nm.

As described above, the thickness of the second gate layer 14 is set equal to or larger than about 0.5 nm, but equal to or smaller than 3.0 nm, whereby the stable high Vth characteristics can be obtained. Now, the reason thereof will hereinbelow be described.

In general, for example, as described in an article of R. B. Wehrsphohn et al., Journal of Applied Physics 87, 144 (2000), it is known that the cause of the Vth shift of the thin film transistor against the gate stress voltage is the injection of the electric charges into the gate insulating layer and/or the generation of the defects in the amorphous silicon semiconductor layer. That is, the phenomenon that Vth is increased against the negative stress voltage is due to the generation of the defects in the amorphous silicon film, and the reduction of Vth is due to the injection of the electric charges into the gate insulating film.

Therefore, as shown in FIG. 3, it is understood that the shift of Vth against the negative stress voltage is due to the generation of the defects in the amorphous silicon film in the case where the thickness of the silicon oxide film is 10 nm, while it is due to the injection of the electric charges into the gate insulating film in the case where no silicon oxide film is formed.

On the other hand, it is understood that as in the thin film transistor according to the present invention, when the thickness of the silicon oxide film is in the range of 0.5 to 3.0 nm, the Vth shift is suppressed. That is, this results from that as shown in the characteristics C of FIG. 3, the increase in Vth is reduced, while Vth is reduced against the relative high stress voltage, and hence the injection of the electric charges into the gate insulating film 14 becomes easy to be generated and also the generation of the defects in the amorphous silicon film is suppressed so that Vth shift is suppressed.

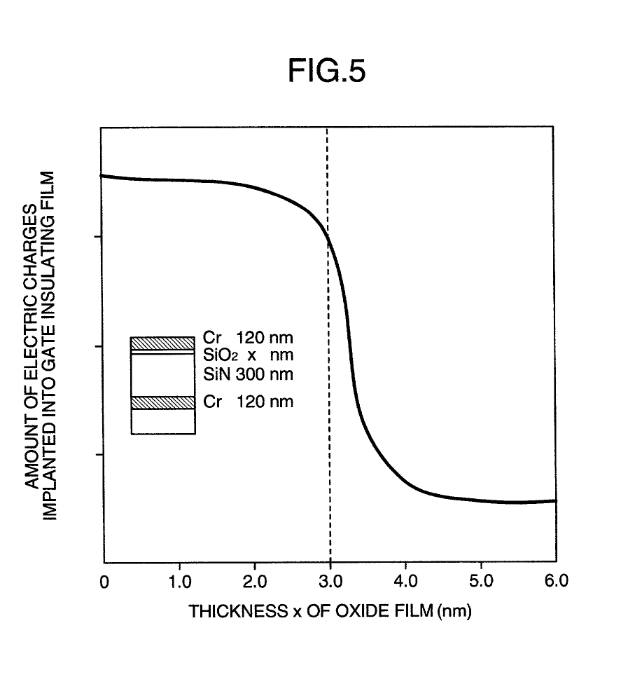

Next, as A result of measuring the dependency of an amount of electric charges injected into the silicon nitride/silicon oxide stacked film on the thickness of the silicon oxide film, the measurement results as shown in FIG. 5 are obtained. In this measurement, in the MIM (Metal Insulator Metal) device in which the thickness of the silicon nitride film is fixed to 300 nm, and the stacked film is sandwiched between the metal electrodes, the stress voltage of −10 V is applied to the metal electrode contacting the silicon oxide film for 1,000 seconds, and under this condition, an amount of injected electric charges against the thickness of the silicon oxide film is measured.

In FIG. 5, in the process of changing the thickness X of the oxide film, when the thickness X of the oxide film is decreased down to the value equal to or smaller than 3.0 nm at which Vth is stabilized, an amount of injected electric charges is abruptly increased to be roughly equal to that in the case of the silicon nitride single layer film. This reason is considered as follows. That is, when the thickness equal to or smaller than 3.0 nm, the electric charges pass through the silicon oxide film (tunnel effect) due to the quantum mechanical effect, and thus the oxide film does not function as the barrier against the injected electric charges.

In addition, the reason that as the silicon oxide film is thinned, an amount of electric charges injected into the insulating film is increased and also the generation of the defects in the amorphous silicon film is suppressed to suppress the Vth shift is considered as follows.

When the electric charges are injected into the insulating film, the internal voltage due to the injected electric charges and the gate stress voltage cancel out each other so that the effective stress voltage applied to the amorphous silicon film is decreased to suppress the generation of the defects. At this time, when the silicon oxide film is thick so as to have a thickness of 10 nm, the injection of the electric charges does not occur, but the stress voltage is applied to the amorphous silicon film to generate the defects. On the other hand, when the silicon oxide film is thinned so as to have a thickness equal to or smaller than 3.0 nm, the injection of the electric charges occurs due to the tunnel effect and hence the stress voltage is relaxed to suppress the generation of the defects in the amorphous silicon film.

On the other hand, as shown in FIG. 4, since when the thickness of the silicon oxide film is equal to or larger than 0.5 nm, Vth shows the fixed value Irrespective of the thickness, it is considered that Vth is not determined on the basis of the thickness of the silicon oxide film, but is determined by the interface between the silicon oxide film and the amorphous silicon film. For this reason, the minimum thickness of the silicon oxide film required to obtain the stationary interface with which Vth becomes equal to or larger than 10 V is about 0.5 nm.

By the way, in the present embodiment, as the silicon oxide film, one which is formed by oxidizing the surface of the silicon nitride film using the O₂ plasma has been described above. However, in the case of the silicon oxide film which is formed by utilizing the plasma enhanced chemical vapor deposition method using the mixed gas of SiH₄ and N₂O, the high Vth characteristics and the stability thereof can not be made compatible with each other.

That is, when the thickness is in the range of 0.5 to 3.0 nm in which Vth is stable, Vth becomes smaller than 10 V, while when the thickness is equal to or larger than 5.0 nm in which Vth equal to or larger than 10 V is obtained, Vth becomes unstable against the negative gate stress voltage. This results from that the oxidation rate when using the O₂ plasma is 0.01 nm/s, whereas the oxide film formation rate when utilizing the plasma enhanced chemical vapor deposition method is 0.1 nm/s which is larger than the former by about one orders of magnitude, and thus in order to form the stationary interface with which Vth becomes equal to or larger than 10 V, about 5.0 nm is required as the thickness of the silicon oxide film at the lowest. However, since when the thickness of the silicon oxide film is equal to or larger than 5.0 nm, the injection of the electric charges into the gate insulating film is suppressed, the stress voltage is not relaxed, and the generation of the defects in the amorphous silicon film is promoted so that Vth becomes unstable.

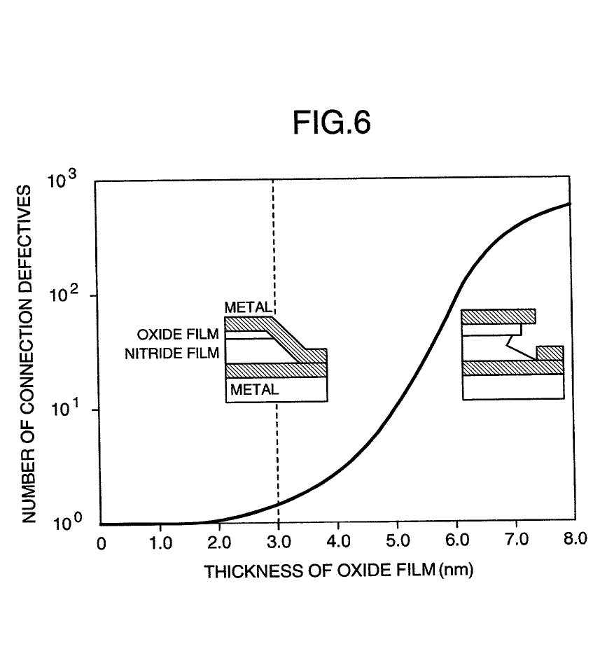

Next, as a result of measuring the dependency of the number of connection defectives on the thickness of the oxide film when a part of the gate insulating film of the thin film transistor according to the present invention is etched and removed to form a process hole, and the metal thin films which are respectively formed on the upper side and the lower side of the gate insulating film with respect to this process hole are electrically connected through the metal layer filled in that process hole, the characteristics results as shown in FIG. 6 are obtained. In this measurement, the connection between the metal thin films having a resistance value showing a certain reference value or More is decided as the connection defective.

From FIG. 6, it is understood that when the thickness of the oxide film is equal to or larger than 3.0 nm, the number of connection defectives is abruptly increased. In order to clear up the cause of this measurement results, as a result of observing the cross sections of the connection parts using the scanning electron microscope, it is found out that the cause of the measurement results results from that when the thickness of the oxide film is equal to or larger than 3.0 nm, the silicon oxide film the etching rate of which is smaller than that of the silicon nitride film is projected in the eaves-like shape on the silicon nitride film, and the metal thin film is broken at the end part of the gate insulating film having the reverse taper shape.

On the other hand, it is confirmed that in the case where the thickness of the oxide film is equal to or smaller than 3 nm, when the process hole passing through a part of the gate insulating film is formed through the gate insulating film consisting of the silicon oxide film and the silicon nitride film, the process hole is formed into the forward taper shape, in which the angle between the end face of the process hole and the insulating substrate surface is smaller than 90 degrees, irrespective of the etching rate, and hence the metal thin films are electrically connected without being broken.

Therefore, it is understood that in order to also ensure the forward taper shape of the gate insulating film, it is necessary to set the thickness of the oxide film to a value equal to or smaller than 3.0 nm. In this case, when the gate electrode or the scanning electrode, and the metal thin film formed in such a way as to overlie the gate insulating film are electrically connected through the metal layer filled in the process hole formed through the gate insulating film, the sufficient electrical connection can be obtained without generating any of cracks in the metal thin film.

As described above, according to the present embodiment, since the second gate insulating layer 14 is formed of the silicon oxide film having a thickness in the range of 0.5 to 3.0 nm, and also the thin film transistor is designed in such a way as to show the characteristics in which when the stress voltage which is negative with respect to the drain electrode and the source electrode is applied to the gate electrode, the operating threshold voltage is reduced, it is possible to realize the thin film transistor showing the stable switching characteristics.

In addition, according to the thin film transistor of the present embodiment, as the operating threshold voltage when releasing the condition of applying the negative stress voltage to the gate electrode, the voltage which is equal to or larger than the liquid crystal driving voltage, e.g., 10 V can be ensured.

When the thin film transistor of the present embodiment is employed in the active matrix type display device, it can be used as a switching device of the display unit or the drive unit.

In addition, when the thin film transistor of the present embodiment is used as a switching device, the thin film transistor of the present embodiment can be applied to an active matrix type liquid crystal display device having the following functions.

For example, the thin film transistor of the present embodiment can be employed in an active matrix type liquid crystal display device based on the IPS system adopting the common wiringless system.

More specifically, it can be employed in an active matrix type liquid crystal display device including one pair of substrates at least one of which is transparent, and a liquid crystal layer held between the one pair of substrates, in which a plurality of scanning wirings and a plurality of signal wirings are formed in a matrix on one of the one pair of substrates; a switching device, a pixel electrode and one set of common electrodes are respectively formed in each of the vicinities of crossing parts at which the scanning wirings and the signal wirings intersect each other; a gate electrode of each of the switching devices is connected to any one of the scanning wirings; a drain electrode of each of the switching devices is connected to any one of the signal wirings; a source electrode of each of the switching devices is connected to the associated one of pixel electrodes; each of the plurality sets of common electrodes are connected to the associated one of the scanning wirings to be arranged between the pixel electrodes; and an electric field which is parallel with each of the one pair of substrates is formed between one of each of the plurality sets of a pixel electrodes and the other of each of the plurality sets of common electrodes.

In addition, the thin film transistor of the present embodiment can be employed in an active matrix type liquid crystal display device based on the vertical electric field system employing the TN liquid crystal.

More specifically, it can be employed in an active matrix type liquid crystal display device including one pair of substrates at least one of which is transparent, and a liquid crystal layer held between the one pair of substrates, in which a plurality of scanning wirings and a plurality of signal wirings are formed in a matrix on one of the one pair of substrates; a switching device, and a pixel electrode are respectively formed in each of the vicinities of crossing parts at which the scanning wirings and the signal wirings intersect each other; a gate electrode of each of the switching devices is connected to any one of the scanning wirings; a drain electrode of each of the switching devices is connected to any one of the signal wirings; a source electrode of each of the switching devices is connected to the associated one of pixel elements; a common electrode is formed in the other of the one pair of substrates; an electric field which is vertical to each of the one pair of substrates is formed between each of the pixel electrodes and the common electrode; the reference voltage is applied to the common electrode; and a liquid crystal driving voltage having the polarity which is changed in the positive direction or the negative direction with respect to the reference voltage is applied to each of the pixel electrodes.

By adopting a thin film transistor according to the present invention in an active matrix type liquid crystal display device, it is possible to contribute to the promotion of the low power consumption and the improvement in the productivity of a liquid crystal device.

With respect to the above description, the following items (1) to (10) are further disclosed herein.

(1) A thin film transistor, wherein A gate electrode, a gate insulating layer, a semiconductor layer, a drain electrode, a source electrode and a passivation insulating layer are fabricated in turn on an insulating substrate; a part, of the gate insulating layer, which is adjacent to the semiconductor layer is made of an oxide film; and when a stress voltage which is negative with respect to the drain electrode and the source electrode is applied to the gate electrode, an operating threshold voltage is reduced.

(2) A thin film transistor according to item (1), wherein the operating threshold voltage when releasing the condition of applying the negative stress voltage to the gate electrode is equal to or larger than a liquid crystal driving voltage.

(3) A thin film transistor according to item (1) or (2), wherein the part, of the gate insulating layer, which is adjacent to the semiconductor layer is formed of a silicon oxide film having a thickness which is equal to or larger than 0.5 nm, but is equal to or smaller than 3.0 nm.

(4) A thin film transistor, wherein a gate electrode, a gate insulating layer, a semiconductor layer, a drain electrode, a source electrode and a passivation insulating layer are fabricated in turn on an insulating substrate; a part, of the gate insulating layer, which is adjacent to the semiconductor layer is made of an oxide film; and the part, of the gate insulating layer, which is adjacent to the semiconductor layer is made of a silicon oxide film having a thickness which is equal to or larger than 0.5 nm, but is equal to or smaller than 3.0 nm.

(5) A thin film transistor according to item (3) or (4), wherein the silicon oxide film has a composition ratio of oxygen to silicon which is equal to or larger than 1.7.

(6) A thin film transistor according to any one of item (1), (2), (3), (4) or (5), wherein a process hole passing through a part of the gate insulating layer is formed through the gate insulating layer; the process hole is formed into a forward taper shape in which an angle between the end face of the process hole and the insulating substrate surface is smaller than 90 degrees; and a metal layer is inserted into the process hole.

(7) A method of manufacturing a thin film transistor, wherein when manufacturing a thin film transistor according to any one of item (1), (2), (3), (4), (5) or (6), the step of forming a first gate insulating layer, made of silicon nitride, as a gate insulating layer on a gate electrode by utilizing the plasma enhanced chemical vapor deposition method, the step of exposing the silicon nitride surface to the oxygen plasma to oxidize the silicon nitride surface to form a second gate insulating layer made of silicon oxide on the first gate insulating layer made of silicon nitride, and the step of forming a silicon semiconductor film as a semiconductor layer on the second gate insulating layer made of silicon oxide by utilizing the plasma enhanced chemical vapor deposition method are continuously implemented without breaking the vacuum.

(8) An active matrix type display device including a switching device in a display unit or a drive unit, wherein a thin film transistor according to any one of items (1) to (6) is included therein as the switching device.

(9) An active matrix type liquid crystal display device including one pair of substrates at least one of which is transparent, and a liquid crystal layer held between the one pair of substrates, in which a plurality of scanning wirings and a plurality of signal wirings are formed in a matrix on one of the one pair of substrates; a switching device, a pixel electrode and one set of common electrodes are respectively formed in each of the vicinities of crossing parts at which the scanning wirings and the signal wirings intersect each other; a gate electrode of each of the switching devices is connected to any one of the scanning wirings; a drain electrode of each of the switching devices is connected to any one of the signal wirings; a source electrode of each of the switching devices is connected to the associated one of pixel elements; each of the plurality sets of common electrodes are connected to the associated one of the scanning wirings to be arranged between the pixel electrodes; and an electric field which is parallel with each of the one pair of substrates is formed between one of each of the plurality sets of pixel electrodes and the other of each of the plurality sets of common electrodes, wherein a thin film transistor according to any one of items (1) to (6) is included therein as the switching device.

(10) An active matrix type liquid crystal display device including one pair of substrates at least one of which is transparent, and a liquid crystal layer held between the one pair of substrates, in which a plurality of scanning wirings and a plurality of signal wirings are formed in a matrix on one of the one pair of substrates; a switching device, and a pixel electrode are respectively formed in each of the vicinities of crossing parts at which the scanning wirings and the signal wirings intersect each other; a gate electrode of each of the switching devices is connected to any one of the scanning wirings; a drain electrode of each of the switching devices is connected to any one of the signal wirings; a source electrode of each of the switching devices is connected to the associated one of pixel elements; a common electrode is formed in the other of the one pair of substrates; an electric field which is vertical to each of the one pair of substrates is formed between each of the pixel electrodes and the common electrode; the reference voltage is applied to the common electrode; and a liquid crystal driving voltage having the polarity which is changed in the positive direction or the negative direction with respect to the reference voltage is applied to each of the pixel electrodes, wherein a thin film transistor according to any one of items (1) to (6) is included therein as the switching device.

While the present invention has been particularly shown and described with reference to the embodiment, it will be understood that the various changes and modifications will occur to those skilled in the art without departing from the scope and true spirit of the invention. The scope of the invention is therefore to be determined solely by the appended claims.

What is claimed is:

1. A thin film transistor, wherein a gate electrode, a gate insulating layer, a semiconductor layer, a drain electrode, a source electrode and a passivation insulating layer are fabricated in turn on an insulating substrate; a part, of the gate insulating layer, which is adjacent to said semiconductor layer is made of an oxide film; and when a stress voltage which is negative with respect to said drain electrode and said source electrode is applied to said gate electrode, an operating threshold voltage is reduced.

2. A thin film transistor according to claim 1, wherein the operating threshold voltage when releasing the condition of applying the negative stress voltage to said gate electrode is equal to or larger than a liquid crystal driving voltage.

3. A thin film transistor according to claim 1, wherein the part, of said gate insulating layer, which is adjacent to said semiconductor layer is formed of a silicon oxide film having a thickness which is equal to or larger than 0.5 nm, but is equal to or smaller than 3.0 nm.

4. A thin film transistor, wherein a gate electrode, a gate insulating layer, a semiconductor layer, a drain electrode, a source electrode and a passivation insulating layer are fabrocated in turn on an insulating substrate; a part, of said gate insulating layer, which is adjacent to said semiconductor layer is made of an oxide film; and the part, of said gate insulating layer, which is adjacent to said semiconductor layer is made of a silicon oxide film having a thickness which is equal to or larger than 0.5 nm, but is equal to or smaller than 3.0 nm.

5. A thin film transistor according to claim 3, wherein said silicon oxide film has a composition ratio of oxygen to silicon which is equal to or larger than 1.7.

6. A thin film transistor according to claim 1, wherein a process hole passing through a part of said gate insulating layer is formed through said gate insulating layer; said process hole is formed into a forward taper shape in which an angle between the end face of said process hole and the insulating substrate surface is smaller than 90 degrees; and a metal layer is inserted into said process hole.

7. A method of manufacturing a thin film transistor, wherein when manufacturing a thin film transistor according to claim 1, the step of forming a first gate insulating layer, made of silicon nitride, as a gate insulating layer on a gate electrode by utilizing the plasma enhanced chemical vapor deposition method, the step of exposing the silicon nitride surface to the oxygen plasma to oxidize the silicon nitride surface to form a second gate insulating layer made of silicon oxide on said first gate insulating layer made of silicon nitride, and the step of forming a silicon semiconductor film as a semiconductor layer on said second gate insulating layer made of silicon oxide by utilizing the plasma enhanced chemical vapor deposition method are continuously implemented without breaking the vacuum.

8. An active matrix type display device including a switching device in a display unit or a drive unit, wherein a thin film transistor according to claim 1 is included therein as the switching device.

9. An active matrix type liquid crystal display device including one pair of substrates at least one of which is transparent, and a liquid crystal layer held between said one pair of substrates, in which a plurality of scanning wirings and a plurality of signal wirings are formed in a matrix on one of said one pair of substrates; a switching device, a pixel electrode and one set of common electrodes are respectively formed in each of the vicinities of crossing parts at which said scanning wirings and said signal wirings intersect each other; a gate electrode of each of said switching devices is connected to any one of said scanning wirings; a drain electrode of each of said switching devices is connected to any one of said signal wirings; a source electrode of each of said switching devices is connected to the associated one of pixel elements; each of the plurality sets of common electrodes are connected to the associated one of said scanning wirings to be arranged between said pixel electrodes; and an electric field which is parallel with each of said one pair of substrates is formed between one of each of the plurality sets of pixel electrodes and the other of each of the plurality sets of common electrodes, wherein a thin film transistor according to claim 1 is included therein as the switching device.

10. An active matrix type liquid crystal display device including one pair of substrates at least one of which is transparent, and a liquid crystal layer held between said one pair of substrates, in which a plurality of scanning wirings and a plurality of signal wirings are formed in a matrix on one of said one pair of substrates; a switching device, and a pixel electrode are respectively formed in each of the vicinities of crossing parts at which said scanning wirings and said signal wirings intersect each other; a gate electrode of each of said switching devices is connected to any one of said scanning wirings; a drain electrode of each of said switching devices is connected to any one of said signal wirings; a source electrode of each of said switching devices is connected to the associated one of pixel elements; a common electrode is formed in the other of said one pair of substrates; an electric field which is vertical to each of said one pair of substrates is formed between each of said pixel electrodes and said common electrode; the reference voltage is applied to said common electrode; and a liquid crystal driving voltage having the polarity which is changed in the positive direction or the negative direction with respect to the reference voltage is applied to each of said pixel electrodes, wherein a thin film transistor according to claim 1 is included therein as the switching device.
